(19) United States
(12) Patent Application Publication
(10) Pub. No.: US 2002/0056923 A1
(43) Pub. Date: May 16, 2002

(54) Semiconductor device with a radiation absorbing conductive protection layer and method of fabricating the same

(76) Inventors: Karsten Wieczorek, Reichenberg-Boxdorf (DE); Frederick N. Hause, Austin, TX (US); Manfred Horstmann, Dresden (DE)

Correspondence Address: J. Mike Amerson, Williams, Morgan & Amerson, P.C., Suite 250, 7676 Hillmont, Houston, TX, 77040, US

(21) Appl. No.: 09/921,027

(22) Filed: Aug. 2, 2001

(30) Foreign Application Priority Data
Nov. 16, 2000 (DE) 100 56 869.6

(51) Int. Cl. H01L 23/48

(52) U.S. Cl. 257/782

(57) ABSTRACT

A method is disclosed in which a lightly doped region in a semiconductor layer is obtained by diffusing dopant atoms of a first and second type into the underlying semiconductor layer. Preferably, the method is applied to the formation of lightly doped source and drain regions in a field effect transistor so as to obtain a required gradual dopant concentration transition from the general region to the drain and source regions for avoiding the hot carrier effect. Advantageously, a diffusion of the dopant atoms is initiated during an oxidizing step in which the thickness of the gate insulation layer is increased at the edge portions thereof.

### BACKGROUND OF THE INVENTION

1. Field of the Invention

The present invention relates to a semiconductor device that exhibits an increased resistance against radiation-induced malfunctions, and, more particularly, relates to a semiconductor device having a reduced penetration rate of α-particles. The present invention further relates to a method of fabricating a semiconductor device having a reduced penetration rate of α-particles.

2. Description of the Related Art

Steadily decreasing feature sizes in modern integrated circuits (ICs) allow fabrication of electronic devices exhibiting complex functionality, within an extremely small volume. Therefore, modem ICs are increasingly used in all types of electronic devices as control units or as storage media, irrespective of whether the device is an everyday product, such as a personal computer, or a device employed in the medical, technical or scientific fields. Among this large number of possible applications of integrated circuits, certain critical applications, e.g., control units in vehicles, medical devices, and the like, require extremely reliable semiconductor devices, such as microprocessors and memory chips, to avoid serious malfunction of the semiconductor device and any peripheral devices connected thereto. Due to the ever-decreasing feature sizes of modem VLSI devices, radiation-induced charge carrier generation in semiconductor devices increasingly proves to be a possible source of failure for the device, which accordingly decreases reliability or even causes a complete failure and, thus, restricts applicability of the device. It has been found that a major source of radiation-induced charge carrier generation is the emission of α-particles from materials of which the semiconductor devices are comprised. In particular, the lead bumps provided in the semiconductor devices to connect to respective leads of the devices have been identified as the main source of α-particles. This adverse effect is further enhanced if the semiconductor device is employed in an environment containing a large amount of highly energetic radiation, as for example in avionics applications, where the density of highly energetic cosmic-ray particles is significantly increased. Substantially two mechanisms contribute to the generation of charge carriers within the semiconductor device, particularly within dielectric layers leading to a charge accumulation, which might then result in a malfunction of the device. First, highly energetic radiation may directly enter inner regions of the semiconductor device and may be absorbed while producing a large number of charged particles, which in turn may then deteriorate the performance of the device. Second, since the lead bumps used in the semiconductor device have a large absorption cross-section, the highly energetic incident radiation will preferably be absorbed in the lead bumps to create a lot of secondary particles possibly including further α-particles which add to the inherently generated α-particles, and may penetrate the underlying device regions, especially when the secondary particles are generated in the vicinity of the interface between the lead and the underlying device.

With reference to FIG. 1, a typical prior art semiconductor device, such as a MOS transistor, will now be described. In FIG. 1, only the relevant portion of the MOS transistor is shown, and persons skilled in the art will readily appreciate that the drawing is merely illustrative, wherein, for the sake of convenience, boundaries between different material layers are illustrated as sharp boundaries, and wherein relative feature sizes are partially exaggerated.

In FIG. 1, a schematic cross-sectional view of an upper portion, i.e., a contact portion, of a semiconductor device is shown. In a dielectric layer 101, a plurality of openings 102 are formed. The openings 102 are filled with an appropriate metal so as to serve as contacts to underlying electrically active regions of the semiconductor device. Over the dielectric layer 101, a passivation layer 103 comprising, for example, SiN, SiO2, SiON, and the like, is formed and patterned to yield openings over the metal contacts in the openings 102. Next, a terminal metal layer 104 comprising, for example, Ta, TaN, TiN, and the like, is deposited and patterned. Metal layer 104 serves as an adhesion layer for Pb/Zn bumps 105 to be formed over the openings 102. Prior to depositing the bumps 105, a polyimide layer 106 is deposited and patterned to yield improved adhesion of the bumps 105 in a final package of the semiconductor device. As previously mentioned, lead is an effective source of α-particles, which, when generated in the vicinity of the interface of bump 105 to the underlying materials 106 and 104, may enter these underlying areas. While the terminal metal layer 104 is able to shield underlying areas, i.e., intrinsic devices, from the α-radiation, the large overlap of bump 105 over isolation layers, such as adhesion layer 106 and passivation layer 103, supports an effective path that allows α-particles and/or secondary particles generated by the initial α-particles to reach the underlying devices, which may result in decreased product reliability and/or a malfunction of the entire semiconductor device, particularly if the semiconductor device is exposed to increased levels of highly energetic radiation, e.g., in avionics or space applications, as previously discussed.

In view of the above-mentioned problems, there exists a need to effectively reduce radiation-induced charge carrier generation in semiconductor devices.

### SUMMARY OF THE INVENTION

According to one aspect of the present invention, a semiconductor device formed on a substrate is provided, the device comprising a dielectric material layer having a plurality of openings filled with a metal for connecting to underlying electrically active regions in the semiconductor device and a conductive protection layer formed over the metal and the dielectric material layer, the conductive protection layer comprising narrow trenches for electrically isolating the openings filled with the metal from each other. The device also comprises a solder bump formed over each of the openings, wherein a lateral distance of two adjacent solder bumps is larger than a width of a narrow trench electrically isolating the two adjacent solder bumps.

According to another aspect of the present invention, a semiconductor device formed on a substrate comprises a plurality of functional elements formed on the substrate, a plurality of contact pads formed over the functional elements and electrically insulated from each other by narrow trenches, the contact pads providing an electrical connection to the functional elements, and comprising as a top layer a PtSi layer, a solder bump provided over each contact pad for electrically connecting the functional elements to the periphery via the contact pads, wherein adjacent two of the solder bumps are insulated from each other by the narrow trenches.

According to another aspect of the present invention, a method of forming a radiation-resistant semiconductor device is provided, the method comprising providing a substrate with at least one electrical device formed thereon, depositing a dielectric material layer over the at least one electrical device and forming a plurality of openings and filling the openings with a metal for providing a connection to electrically active regions of the at least one device. The method also comprises forming a conductive protection layer over the dielectric material layer and the openings filled with the metal, forming narrow trenches between adjacent openings so as to electrically insulate the openings filled with the metal from each other and forming a solder bump over each opening such that a lateral extension of the solder bump is less than a distance between adjacent narrow trenches substantially extending in the same direction.

The method of forming a radiation resistance semiconductor device in accordance with the present invention allows the formation of a semiconductor device having the same advantages and features as previously pointed out. Further advantages and embodiments are defined in the dependent claims.

### BRIEF DESCRIPTION OF THE DRAWINGS

The invention may be understood by reference to the following description taken in conjunction with the accompanying drawings, in which like reference numerals identify like elements, and in which:

FIG. 1 schematically shows a cross-sectional view of a portion of a typical prior art semiconductor device; and

FIGS. 2a-2e show schematic cross-sectional views of a portion of a semiconductor device during various stages of the manufacture of the semiconductor device in accordance with one embodiment of the present invention.

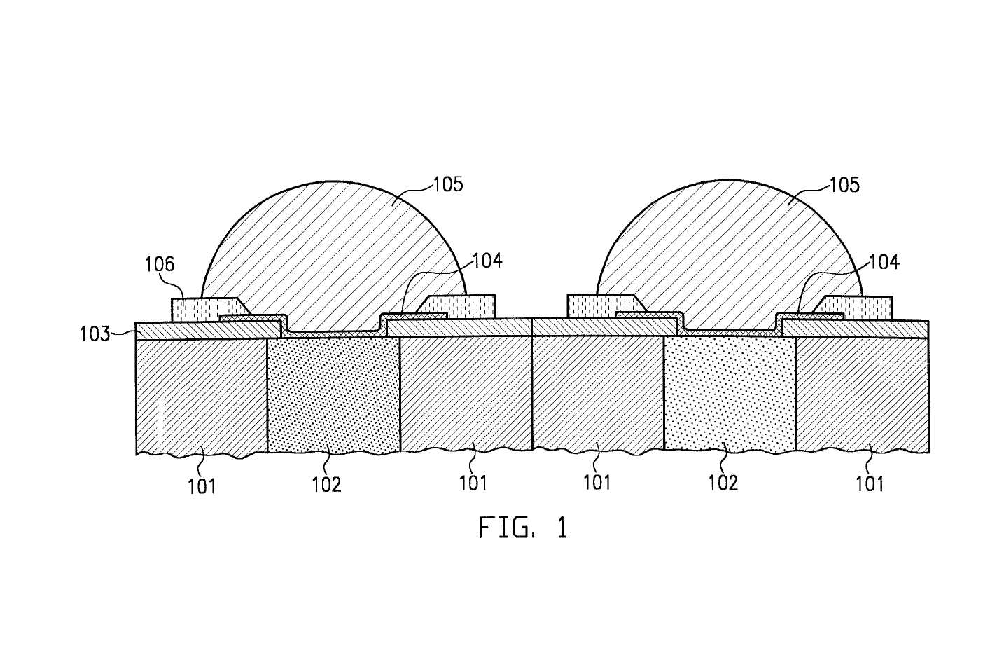

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

Moreover, various process steps as described below may be performed differently depending on particular design requirements. Furthermore, in this description only the relevant steps of the manufacture and the portions of the device necessary for understanding of the present invention are considered.

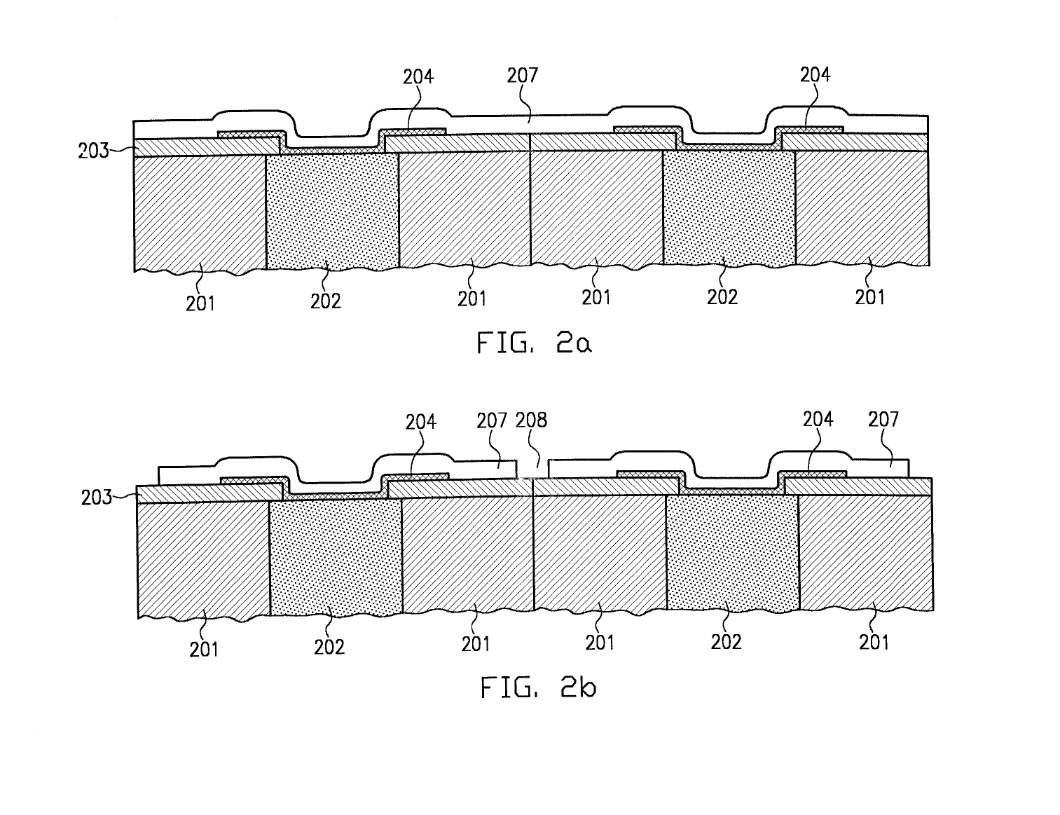

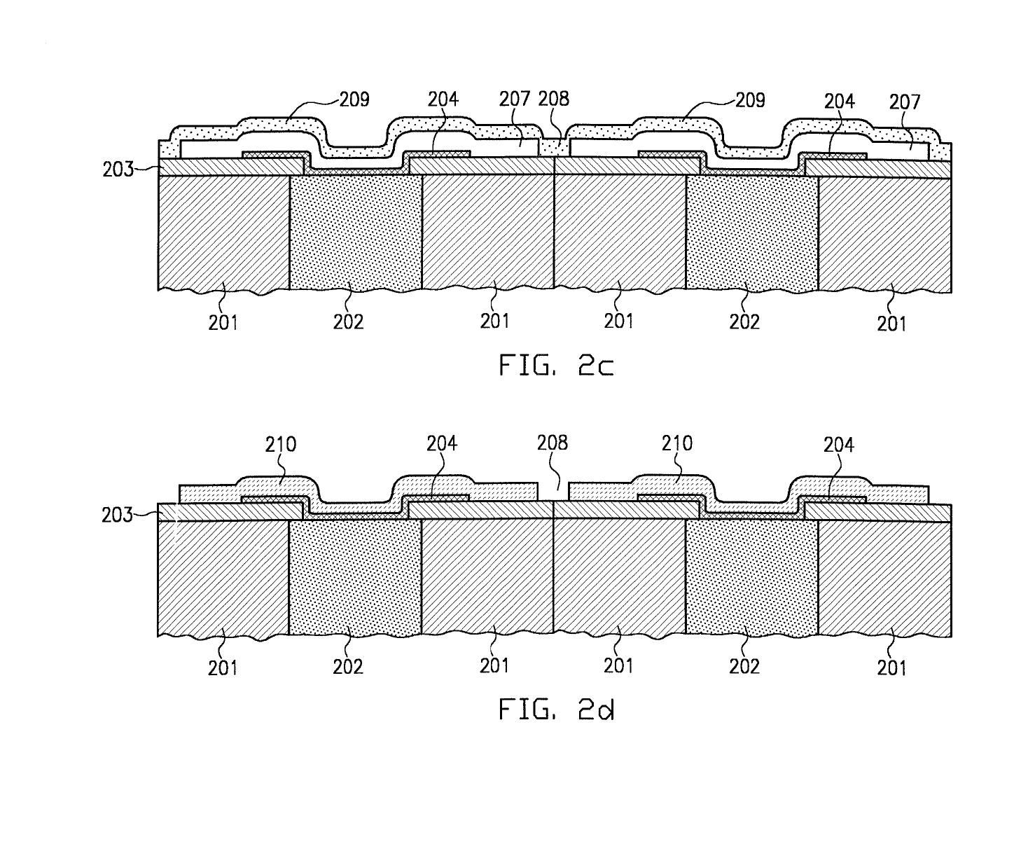

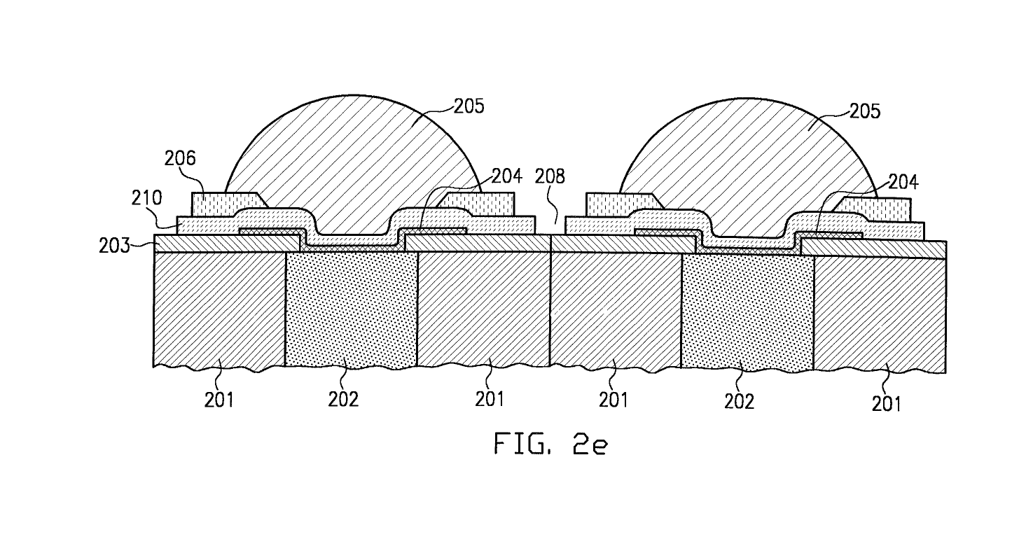

With reference to FIGS. 2a-2e, an illustrative example of forming a semiconductor device exhibiting an improved resistivity against radiation-induced charge carrier generation in accordance with one embodiment of the present invention will now be described. In FIG. 2a, openings 202 are formed in a dielectric material layer 201. Openings 202 are filled with a conductive material such as aluminum, copper, tungsten, and the like, for providing electrical contact to one or more underlying electric devices, which are not shown in the figures. As is well-known to a person skilled in the art, sidewalls of the openings may be coated with an appropriate barrier layer prior to the filling with conductive material. A passivation layer 203 has been deposited over the dielectric material layer 201 and openings have been formed in the passivation layer 203 so as to expose the conductive material in the openings 202. A further metal layer 204 may be deposited over the entire wafer surface. The metal layer 204 is then patterned and etched by convetional photolithography and anisotropic etching, thus covering the metal in the opening 202 and partially over the passivation layer 203. Finally, a relatively thick silicon layer 207 is blanket-deposited over the passivation layer 203 and the metal layer 204 by CVD deposition. The thickness of the silicon layer 207 is selected so as to exceed several absorption lengths for α-particles having an energy up to about 1-20 MeV.

FIG. 2b shows the semiconductor device of FIG. 2a after the silicon layer 207 has been patterned by photolithography and anisotropic etching so as to form narrow trenches 208 isolating adjacent openings 202 from each other. The width of the shallow trenches 208 is determined by the photolithographical masking and, hence, can be made with high precision and, thus, significantly smaller than a distance between adjacent solder bumps, which have to be formed over adjacent openings 202. Moreover, silicon is known to effectively shield α-particles and to inherently emit α-particles with a rate that may be lower than about 0.005 α-particles per cm2 per hour. Thus, the number of α-particles that are inherently produced in the silicon layer 207 is extremely low and, hence, no device degradation will occur due to α-particles from the silicon layer 207 substantially covering the entire surface of the semiconductor device, except for the small area of the narrow trenches 208.

FIG. 2c shows the semiconductor device of FIG. 2b, wherein a platinum layer 209 is deposited over the silicon layer 207. A thickness of the platinum layer 209 is selected so as to ensure that the entire silicon of the silicon layer 207 will react with the platinum of the platinum layer 209 in a subsequent heat treatment. Preferably, the platinum of the platinum layer 209 is a high-purity platinum so as to have a very low intrinsic α-particle emission rate. This intrinsic emission rate is preferably about 0.005 α-particles per cm² per hour or less. As is well known, platinum has an extremely small full mean path for α-particles due to its high atomic number so that α-particles penetrating a thin platinum layer are most effectively stopped to shield underlying regions. Since no process for patterning a pure platinum layer is known that is compatible with standard semiconductor manufacturing processes, a heat treatment, such as a rapid thermal anneal process, is performed to convert the silicon layer 207 and the platinum layer 209 into a platinum silicide layer that allows patterning in further processes, yet providing the advantages of low intrinsic α-emission rate, low resistance, and high absorption of radiation, particularly of α-particles. Since this solid state reaction can be initiated at temperatures below 400° C., neither aluminum-based nor copper-based back end integration schemes are disadvantageously affected.

FIG. 2d shows the device of FIG. 2c, wherein excess platinum that has not reacted with the silicon during the rapid thermal annealing cycle, in particular in the narrow trenches 208, has selectively been removed, for example by means of aqua regia. Since the thickness of the platinum layer 209 has been selected so as to effect a complete reaction of the silicon in the silicon layer 207, a platinum silicide layer 210 has been formed that is in immediate contact with metal layer 204, ensuring a low resistance between the metal layer 204 and the platinum silicide layer 210. Furthermore, the platinum silicide layer 210 covers the vast majority of the wafer surface, except where the narrow trenches 208, having a small width of about 0.25 to about 1 μm, isolate unrelated openings 202 from each other.

In FIG. 2e, the device of FIG. 2d is shown, wherein a polyimide layer 206 has been formed in a conventional manner and wherein subsequently solder bumps 205 consisting of Pb/Zn have been deposited over the openings 202. As can be seen in FIG. 2e, a lateral extension of the platinum silicide layer 210 that serves as a conductive protection layer is significantly larger than a lateral extension of the solder bump 205, since the lateral extension of the platinum silicide layer 210 is defined by photolithography and etching and, therefore, remarkably narrow spacings between adjacent portions of the platinum silicide layer 210 can be established compared to the spacing of adjacent solder bumps 205. Accordingly, α-particles that are generated during the decay of Pb atoms of the solder bumps in the vicinity of an interface between the solder bump 205 and underlying material, such as polyimide layer 206 or the platinum silicide layer 210, are effectively shielded from penetrating underlying semiconductor devices, such as FET transistors and the like. The thickness of the platinum silicide layer 210 is preferably selected so as to efficiently stop α-particles having an energy of about 15 MeV or less. Moreover, since the vast majority of the semiconductor surface is covered by the platinum silicide layer 210, i.e., the entire surface is covered except for the narrow trenches 208, penetration of external highly energetic radiation is remarkably reduced due to the high absorption cross-section of PtSi. Similarly, secondary particles created in the solder bumps 205 by incident highly energetic radiation are also effectively prevented from penetrating the underlying material layers. As already pointed out, using high-purity platinum and silicon keeps the inherent α-particle generation rate extremely small, so that the advantageous shielding effect is obtained without generating any additional inherent α-particles in the platinum silicide layer 210. It should be noted that the metal layer 204 has been formed over the openings 202 after filling with a metal, but the semiconductor device may alternatively be formed without an intermediate layer between the platinum silicide layer 210 and the metal in the openings 202. A person skilled in the art will also readily appreciate that the inventive conductive protection layer may be provided in any semiconductor device such as microprocessors, memory chips, and the like. The inventive conductive protection layer is most advantageous in VLSI circuits, wherein extremely small feature sizes of about 0.25 μm and less bear a high risk of device degradation due to radiation-induced charge carrier generation. Furthermore, the present invention is not limited to semiconductor devices based on silicon, but may also be applied to other semiconductor devices based on materials such as germanium, GaAS and other III-V, and II-VI semiconductor materials.

Advantageously, in a semiconductor device in accordance with the present invention, the conductive protection layer substantially covers the entire surface, except for the narrow trenches, of the semiconductor device over which solder bumps are arranged, the solder bumps having a lateral extension that is smaller than the lateral extension of the conductive protection layer enclosed between respective narrow trenches. In this manner, α-particles that are emitted by the solder bumps in a direction toward the underlying material layers are effectively absorbed within the conductive protection layer. Accordingly, charge carrier generation due to incident α-particles, especially in dielectric material layers, is effectively eliminated so that charge carrier accumulation due to inherently generated α-particles no longer affects the performance of underlying devices, such as FET transistors, capacitors, and the like. Moreover, the devices underlying the conductive protection layer are also more reliably shielded from external highly energetic radiation, since only the narrow trenches isolating individual contact regions from each other are exposed to external radiation.

If the inherent α-particle emission rate of the conductive protection layer is selected to be less than about 0.005 α-particles per cm² per hour, the α-particles of the overlying solder bumps are effectively shielded, while on the other hand the inherent emission rate of the conductive protection layer is extremely small so that α-particles emitted from the conductive protection layer substantially do not attribute to device deterioration.

Advantageously, the conductive protection layer may comprise platinum silicide which exhibits an extremely low intrinsic α-particle emission rate and also shows a high absorption cross-section for α-particles. Furthermore, silicon and platinum react at a temperature below 400° C. Therefore, the process of a formation of platinum silicide is compatible with previous manufacturing processes, particularly with aluminum and copper back-end processing, so that forming platinum silicide does not disadvantageously affect the characteristics of the semiconductor device, especially the overall resistivity of the contact between the solder bumps and the device is not deteriorated due to the low resistivity of PtSi.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified fled and all such variations are considered within the scope and spirit of the invention. Accordingly, the protection sought herein is as set forth in the claims below.

What is claimed:

1. A semiconductor device formed on a substrate, the device comprising:
a dielectric material layer having a plurality of openings filled with a metal for connecting to electrically active regions in the device;
a conductive protection layer formed over the metal and the dielectric material layer, the conductive protection layer having narrow trenches for electrically isolating the metal filled openings from each other; and
a solder bump formed over each of the openings, wherein a lateral spacing of two adjacent solder bumps is larger than a width of a narrow trench electrically isolating the two adjacent solder bumps.

2. The semiconductor device of claim 1, wherein the conductive protection layer comprises a material having a high cross-section for stopping α-particles.

3. The semiconductor device of claim 1, wherein the thickness of the conductive protection layer is adjusted to effectively stop α-particles having energies up to about 5 MeV.

4. The semiconductor device of claim 1, wherein an inherent α-particle emission rate of the conductive protection layer is less than about 0.01 α-particles per cm² per hour.

5. The semiconductor device of claim 1, wherein an inherent α-particle emission rate of the conductive protection layer is less than about 0.005 α-particles per cm² per hour.

6. The semiconductor device of claim 1, wherein the conductive protection layer comprises platinum silicide.

7. The semiconductor device of claim 1, wherein the solder bump comprises lead, and α-particles emitted by the solder bump are effectively blocked by the conductive protection layer.

8. A method of forming a lightly doped region in a semiconductor device comprising:
providing a substrate comprising a semiconductor region in an upper portion thereof;
forming a first dielectric layer of the substrate, the first dielectric layer comprising dopant atoms of a first type having a first concentration and a first diffusion length with respect to the material of the semiconductor region;
forming a second dielectric layer over the first dielectric layer, the second dielectric layer comprising dopant atoms of a second type and a second concentration and a second diffusion length with respect to the material of the semiconductor region; and
applying a predefined temperature for a predefined time period to the substrate to allow dopant atoms of the first and second type to enter the semiconductor region to create a lightly doped region in the semiconductor region with a shape and a local dopant concentration that depend on the predefined temperature, the predefined time period, the first and second concentrations, and first and second diffusion length.

9. The method of claim 8, further comprising performing a heat treatment prior to the formation of the second dielectric layer to allow dopant atoms of the first type to enter the semiconductor region.

10. The method of claim 8, further comprising forming a gate electrode over the semiconductor region with a gate insulation layer electrically insulating the gate electrode from the semiconductor region.

11. The method of claim 10, wherein the first dielectric layer is formed by oxidizing the substrate and the gate electrode material, wherein dopant atoms of the first type are added to the oxidizing ambient.

12. The method of claim 11, wherein the gate insulation layer comprises an oxide, and a thickness of the gate insulation layer at the corner portions thereof is increased during the formation of the first dielectric layer.

13. The method of claim 10, wherein forming the second dielectric layer comprises patterning of the second dielectric layer to form sidewall spacers adjacent to sidewalls of the gate electrode.

14. The method of claim 8, wherein the second dielectric layer is formed by chemical vapor deposition and the concentration of the dopant atoms of the second type is adjusted by feeding a gaseous component with a specified flow rate during deposition of the second dielectric layer.

15. The method of claim 8, wherein the first dielectric layer comprises two or more dopant atoms of different types, each type of dopant atom having a different one of valency and diffusion length.

16. The method of claim 8, wherein the second dielectric layer comprises two or more dopant atoms of different types, each type of dopant atom having a different one of valency and diffusion length.

17. The method of claim 8, wherein the first dielectric layer comprises one of n-type and p-type dopant atoms.

18. The method of claim 8, wherein the second dielectric layer comprises one of n-type and p-type dopant atoms.
